(19) United States
(12) Patent Application Publication
(10) Pub. No.: US 2012/0037803 A1
(43) Pub. Date: Feb. 16, 2012

(54) ELECTROMAGNETIC INTERFERENCE SHIELD

(75) Inventor: William B. Strickland, Lake Oswego, OR (US)

(73) Assignee: FLIR SYSTEMS, INC., Wilsonville, OR (US)

(21) Appl. No.: 12/855,666

(22) Filed: Aug. 12, 2010

(51) Int. Cl. G01J 5/00; H05K 13/00; G01J 1/04

(52) U.S. Cl. 250/338.1; 250/227.11; 29/592.1

(57) ABSTRACT

An improved EMI shielded detection system. The disclosed system may include features configured to increase radio wave and microwave absorbance while retaining significant transparency at visible and/or infrared wavelengths, thus increasing EMI shielding efficiency. This may be accomplished through the use of a conductive mesh having appropriately chosen dimensions and spacing, and embedded in a transparent medium. To minimize the impact of the mesh on the effective aperture of the medium, the strands of the mesh may be made relatively narrow, and to provide sufficient shielding despite the narrow strand width, the mesh may be embedded relatively deeply in the medium.

### INTRODUCTION

Imaging systems may include electro-optical photodetectors that generate discrete electronic signals in response to incident photons, such as visible light or non-visible ultraviolet (UV) or infrared (IR) radiation. For example, digital cameras may focus an optical image onto a focal plane array that generates electronic signals representative of the image, which then may be processed, displayed, and/or recorded. Digital imaging systems may provide substantial utility advantages over other (e.g., photochemical) systems, such as sensitivity, response range, temporal density, dynamic filtering, and quantitative analysis. However, electro-optical signaling and control circuits may be disrupted by electromagnetic interference (EMI), such as microwave radiation or radio wave radiation, which can induce indiscrete electrical currents in conductive materials. Some electro-optical systems, such as certain surveillance, satellite, and weapon systems, may be required to image optical fields containing high-intensity EMI.

EMI shields, as used herein, include systems that block or substantially attenuate microwave and/or radio wave radiation. An EMI shield may block interfering radiation by absorbance and/or reflectance. EMI shields typically include an electrically conductive material layer interposed between a potential source of interfering radiation and a susceptible electronic device. For example, an EMI shield may include a thin conductive metal layer that blocks a substantial portion of EMI radiation while transmitting a substantial portion of the incident optical radiation. Alternatively, an EMI shield may include a conductive grid, where spaces through the grid have dimensions that are smaller than wavelengths of the EMI radiation and larger than wavelengths of radiation to be detected, thereby selectively blocking EMI while transmitting a portion of the desired radiation through the spaces.

In some cases, EMI filtering efficiency (e.g., detection band transmittance relative to EMI band transmittance) can be selectively increased for a portion of the optical spectrum. For example, some optical EMI shields include conductive composite materials, such as indium tin oxide, which are substantially transparent to visible light but are opaque to infrared radiation. However, even when such composite materials are used, system performance is still compromised as the thickness of film or width of mesh strands increases. Accordingly, a need remains for EMI shielding techniques that improve EMI filtering efficiency in desired wavelength ranges.

### SUMMARY

The present teachings disclose an improved EMI shielded detection system, including apparatus and methods of use. The disclosed system may include features configured to increase blockage of radio wave and/or microwave radiation while retaining significant transparency at visible and/or infrared wavelengths, thus increasing EMI shielding efficiency. This may be accomplished through the use of a conductive mesh having appropriately chosen dimensions and spacing, and embedded in a transparent medium. To minimize the impact of the mesh on the effective aperture of the medium, the strands of the mesh may be made relatively narrow, and to provide sufficient shielding despite the narrow strand width, the mesh may be embedded relatively deeply in the medium.

### BRIEF DESCRIPTION OF THE DRAWINGS

FIG. 1 is an isometric view of an aerial stabilized optical imaging system mounted on a helicopter, in accordance with aspects of the present teachings.

FIG. 2 is a schematic sectional view of an EMI shielded optical imaging system payload disposed within a gimbal housing, such as the housing visible in FIG. 1, in accordance with aspects of the present teachings.

FIG. 3 is a schematic sectional view of an exemplary prior art EMI shielding system, including a conductive mesh disposed at the surface of a transparent material.

FIG. 4 is a top view of the prior art EMI shielding system of FIG. 3.

FIG. 5 is a schematic sectional view of an exemplary EMI shielding system in accordance with aspects of the present teachings, including a conductive mesh embedded within a transparent material.

FIG. 6 is a top view of the EMI shielding system of FIG. 5.

FIG. 7 is a graph plotting electromagnetic transmittance as a function of grid spacing for conductive mesh of various widths.

FIG. 8 is a graph plotting shielding effectiveness as a function of grid spacing for aluminum mesh of various widths and thickness 0.5 micrometers.

FIG. 9 is a graph plotting shielding effectiveness as a function of grid spacing for aluminum mesh of various thicknesses and width 1.0 micrometers.

FIG. 10 is a flowchart illustrating a method of EMI shielding, in accordance with aspects of the present teachings.

### DEFINITIONS

Technical terms used in this disclosure have the meanings that are commonly recognized by those skilled in the art. However, the following terms may have additional meanings, as described below. The wavelength ranges identified in these meanings are exemplary, not limiting, and may overlap slightly, depending on source or context. The wavelength ranges lying between about 1 nm and about 1 mm, which include ultraviolet, visible, and infrared radiation, and which are bracketed by x-ray radiation and microwave radiation, may collectively be termed optical radiation. The wavelength ranges lying above about 1 mm, which include microwave radiation and radio waves, may collectively be termed the radio spectrum.

Ultraviolet radiation. Electromagnetic radiation invisible to the human eye and having wavelengths from about 100 nm, just longer than x-ray radiation, to about 400 nm, just shorter than violet light in the visible spectrum. Ultraviolet radiation includes (A) UV-C (from about 100 nm to about 280 or 290 nm), (B) UV-B (from about 280 or 290 nm to about 315 or 320 nm), and (C) UV-A (from about 315 or 320 nm to about 400 nm).

Visible light. Electromagnetic radiation visible to the normal human eye and having wavelengths from about 360 or 400 nanometers, just longer than ultraviolet radiation, to about 760 or 800 nanometers, just shorter than infrared radiation. Visible light typically may be imaged and detected by the unaided human eye and includes violet (about 390-425 nm), indigo (about 425-445 nm), blue (about 445-500 nm), green (about 500-575 nm), yellow (about 575-585 nm), orange (about 585-620 nm), and red (about 620-740 nm) light, among others.

Infrared (IR) radiation. Electromagnetic radiation invisible to the human eye and having wavelengths from about 700 nanometers, just longer than red light in the visible spectrum, to about 1 millimeter, just shorter than microwave radiation. Infrared radiation includes (A) IR-A (from about 700 nm to about 1,400 nm), (B) IR-B (from about 1,400 nm to about 3,000 nm), and (C) IR-C (from about 3,000 nm to about 1 mm). IR radiation, particularly IR-C, may be caused or produced by heat and may be emitted by an object in proportion to its temperature and emissivity. Portions of the infrared having wavelengths between about 3,000 and 5,000 nm (i.e., 3 and 5 μm) and between about 7,000 or 8,000 and 14,000 nm (i.e., 7 or 8 and 14 μm) may be especially useful in thermal imaging, because they correspond to minima in atmospheric absorption and thus are more easily detected (particularly at a distance). The particular interest in relatively shorter wavelength IR has led to the following classifications: (A) near infrared (NIR) (from about 780 nm to about 1,000 nm), (B) short-wave infrared (SWIR) (from about 1,000 nm to about 3,000 nm), (C) mid-wave infrared (MWIR) (from about 3,000 nm to about 6,000 nm), (D) long-wave infrared (LWIR) (from about 6,000 nm to about 15,000 nm), and (E) very long-wave infrared (VLWIR) (from about 15,000 nm to about 1 mm). Portions of the infrared, particularly portions in the far or thermal IR having wavelengths between about 0.1 and 1 mm, may alternatively, or in addition, be termed millimeter-wave (MMV) wavelengths.

Microwave Radiation. Electromagnetic radiation invisible to the human eye and having wavelengths from about 1 millimeter, just longer than infrared radiation, to about 1 meter, just shorter than radio waves.

Radio Waves. Electromagnetic radiation invisible to the human eye and having wavelengths greater than about 1 meter, just longer than microwave radiation. In practice, radio waves typically have wavelengths less than about 100,000 kilometers, which corresponds to extremely low frequency waves.

Window. Any solid medium at least partially transparent to electromagnetic radiation, within which a material may be embedded in a mesh pattern. Windows, as described herein, may include substantially planar (i.e., non-focusing) materials, curved or Fresnel lenses, filters, and/or the like.

### DETAILED DESCRIPTION

The present teachings provide a system, including apparatus and methods, for filtering EMI radiation, such as microwave radiation and/or radio waves, in the field of view of an image detector, thereby increasing the potential image quality for fast imaging devices that require shielding against high intensity EMI radiation. The apparatus may include a housing that substantially surrounds the detector and that includes one or more selectively transparent media or windows configured to substantially transmit radiation in the desired detection wave band while preventing substantial passage of undesirable EMI radiation. The apparatus may also include an optical relay structure to direct radiation transmitted through the selectively transparent medium onto the detector.

The window, to shield against EMI radiation, may include an integrated conductive mesh connected to an electrical ground, where the mesh is configured to be substantially transmissive to radiation in one or more particular wavelength regimes and substantially opaque to radiation in one or more other wavelength regimes. For example, the window may be configured to allow substantial passage of radiation (such as visible light or infrared radiation) having wavelengths less than a predetermined wavelength threshold into the housing, while preventing substantial passage of radiation (such as microwave radiation or radio waves) having wavelengths greater than the threshold. Thus, depending on the embodiment, the threshold may be about 0.1 mm, about 1 mm, or about 10 mm, among others. The mesh may be embedded within the medium in a manner that minimizes the impact of the mesh on the effective aperture of the medium. More specifically, the mesh may be formed of strands having oblong cross-sections, with the long axis of the cross-section aligned perpendicular to a surface of medium, and the short axis aligned parallel to the surface. For example, the mesh may be formed of metal disposed inside an interconnected pattern of deep grooves crossing or crisscrossing the surface of the medium. Disposing the mesh inside the medium, particularly a monolithic medium, may reduce the likelihood that strands of the mesh will be broken, as might be caused by mechanical abrasion of strands positioned on a surface of the medium.

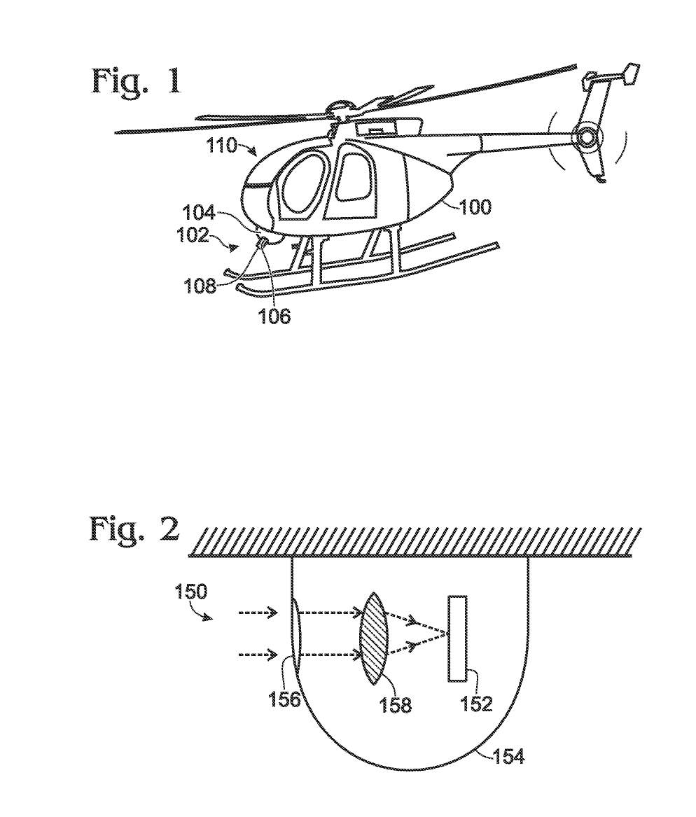

FIG. 1 depicts a helicopter 100 equipped with a shielded detection system, generally indicated at 102, according to aspects of the present teachings. Detection system 102 may include a housing 104 within which a gimbal (or gimbals) (not shown in FIG. 1) is disposed and configured to selectively reorient portions of the system mounted to the gimbal as a payload, typically around two or more axes. Housing 104 includes an aperture 106, within which a selectively transparent medium such as a window, a lens, or an optical device 108 including a window or lens may be disposed. Image data such as visible light, infrared radiation, and/or millimeter-wave radiation may pass through optical device 108 and into housing 104, to be collected by a detector. The collected imagery may be corrected or otherwise processed, recorded, and/or displayed on a heads-up display, generally indicated at 110 in FIG. 1. Thus, a pilot of helicopter 100 may use system 102 to view imagery in real time on display 110.

The detection systems provided by the present teachings more generally may be configured for use with any suitable support platform (or no platform at all). Support platform, as used herein, generally refers to any mechanism for holding, bearing, and/or otherwise presenting the detection system. The support platform may be moving, movable but stationary, or fixed in relation to the earth, and may be disposed on the ground, in the air or space, or on and/or in water, among others. In any case, the support platform may be selected to complement the function of the detection system. The support platform may be movable, such as a vehicle. Exemplary vehicles include a ground vehicle (e.g., a car, truck, motorcycle, tank, etc.), a watercraft (e.g., a boat, submarine, carrier, etc.), an aircraft or airborne device (e.g., a fixed-wing piloted aircraft, pilotless remote-controlled aircraft, helicopter (as in FIG. 1), drone, missile, dirigible, aerostat balloon, rocket, etc.), or the like. The support platform may be fixed in position. Exemplary fixed support platforms may include a building, an observation tower, and/or an observation platform, among others. In some embodiments, the support platform may be a temporarily stationary movable support, such as a hovering helicopter and/or a parked car, truck, or motorcycle, among others. Exemplary applications for a gimbal system include navigation, targeting, search and rescue, law enforcement, firefighting, and/or surveillance, among others.

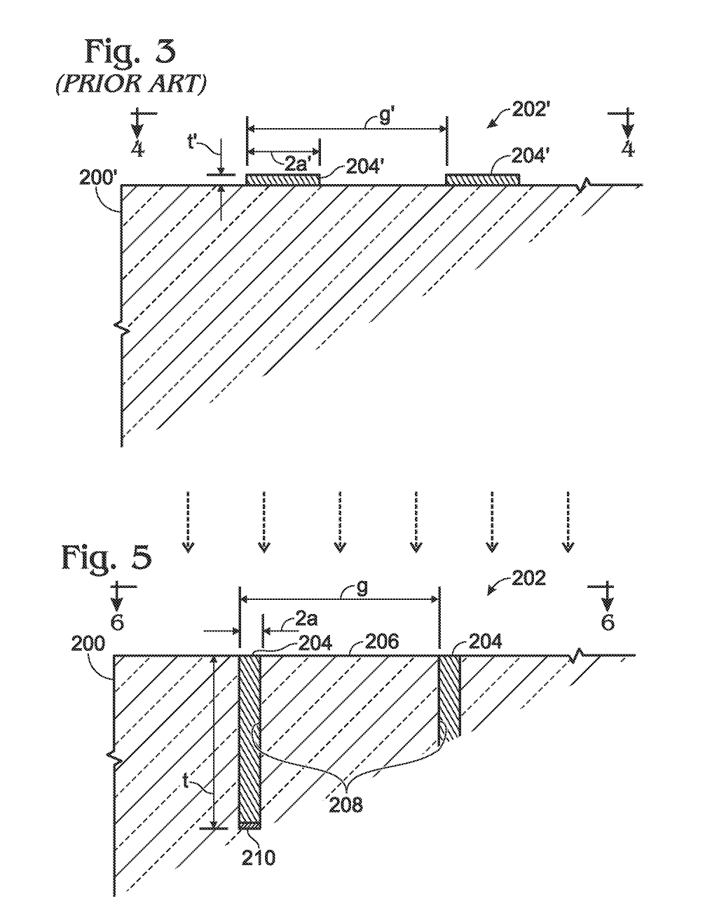

FIG. 2 shows additional details of a detection system, generally indicated at 150, according to aspects of the present teachings. System 150 includes a detector 152, a housing 154, a window 156, and an optical relay structure 158, as described below.

Detector 152 is configured to detect radiation and optionally to convert it into a signal. The detector may, for example, be an infrared radiation detector configured to detect infrared radiation, a visible light detector configured to detect visible light, or a detector that detects radiation in some other wavelength regime or in a combination of two or more wavelength regimes. The detector may take the form of a focal plane array, charge-coupled device (CCD), phototube, photodiode array, and/or any other suitable device configured to detect radiation in the desired wavelength regime(s). In some embodiments, there may be two or more detectors, configured to detect radiation in two or more wavelength regimes (e.g., infrared and visible, among others) and/or to detect two or more aspects of the radiation (e.g., intensities in different planes of polarization, among others).

Housing 154 at least substantially surrounds detector 152, which in some cases may be mounted on a gimbal (not shown) or similar structure configured to allow selective rotation of the detector. Housing 154 includes or incorporates a selectively transparent window 156, which is substantially transparent to radiation in one or more wavelength regimes, such as the infrared and/or visible regimes. Window 156 typically will be configured to be transparent to a wavelength regime that is similar to or overlapping with a regime detectable by detector 152. Window 156 may take the form of a planar (non-focusing) material, a lens, a filter, or any other structure that is substantially transparent to a desired range of electromagnetic wavelengths. Window 156 also has the property that it is substantially opaque or non-transmissive to at least some other wavelengths such as EMI wavelengths, as described in more detail below.

Optical relay structure 158 is operatively disposed between selectively transparent window 156 and detector 152 and is configured to focus and/or direct radiation transmitted through the window onto the detector. For simplicity, optical relay structure 158 is depicted as a lens in FIG. 2; however, more generally, the relay structure may take the form of one or a plurality of lenses, mirrors, and/or other optical components that receive incoming radiation through window 156 and direct, focus, or otherwise process the radiation before it arrives at detector 152, as indicated schematically by the dashed lines in FIG. 2. In embodiments having two or more detectors, radiation may be directed toward the detectors by a shared optical relay structure, by separate optical relay structures, or by combinations thereof.

Further aspects of the detection system, including components and examples thereof, are described in the following U.S. patent documents, which are incorporated herein by reference in their entireties for all purposes: U.S. Pat. No. 7,264,220, issued Sep. 4, 2007; U.S. Pat. No. 7,561,784, issued Jul. 14, 2009; U.S. Pat. No. 7,471,451, issued Dec. 30, 2008; U.S. Pat. No. 7,671,311, issued Mar. 2, 2010; and U.S. Provisional Patent Application Ser. No. 61/296,336, filed Jan. 19, 2010.

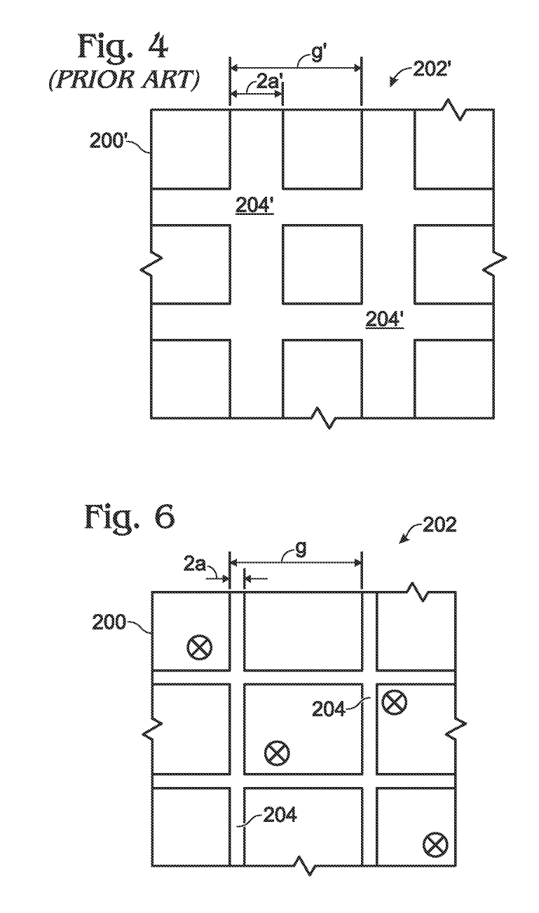

FIGS. 3 and 4, for purposes of comparison with the present teachings, show a magnified schematic sectional view and a top view, respectively, of a portion of a prior art selectively transparent medium 200′. Medium 200′ includes a conductive grid, generally indicated at 202′. Grid 202′ is configured to act as an EMI shield by selectively preventing substantial passage of electromagnetic radiation of certain types, such as microwave radiation and/or radio waves.

Grid 202′ is formed on the surface of medium 200′. The grid typically has a thickness t′ between approximately 500 Å and 0.5 μm. The characteristic spacing g′ between adjacent strands 204′ of the grid approximately determines the maximum wavelength that will penetrate the grid substantially unaffected, i.e., radiation with wavelengths greater than g′ will be shielded to some extent from passing through the medium.

EMI shielding grids are generally designed with two desired features in mind: high optical transmission of detection-band radiation and high reflection of unwanted EMI-band radiation. High optical transmission is obtained by minimizing the width 2a′ of grid strands 204′. High EMI reflection requires minimizing the sheet resistance of the grid. Unfortunately, these two requirements are in conflict, because a low sheet resistance is obtained with wider and/or thicker lines, and wider lines reduce optical transmission. Thicker lines are limited by the inherent limitations of photoresist and other metal deposition processes that may be used to form the grid.

FIGS. 5 and 6, in contrast, show a magnified schematic sectional view and a top view, respectively, of selectively transparent medium 200 according to aspects of the present teachings. A conductive mesh configured to act as an EMI shield is generally indicated at 202. The mesh includes a plurality of mesh strands 204 characterized by a width 2a, a thickness t, and a separation distance g. Comparison of FIGS. 5 and 6 with FIGS. 3 and 4 shows various distinctions between medium 200 and prior art medium 200′. In particular, the width of strands 204 is significantly less than the width of strands 204′ (i.e., a<a′), whereas the thickness of strands 204 is significantly greater than the thickness of strands 204′ (i.e., t>t′). Furthermore, strands 204 are embedded within medium 200 rather than being disposed on a top or outer surface 206 of the medium. Incident radiation is shown as vertical arrows in FIG. 5 and as [symbol] , representing the tails of the arrows, in FIG. 6.

Conductive mesh 202 may, for example, be formed in medium 200 using any suitable process, including deep ion etching, laser scribing, and/or other forms of etching, followed by vapor deposition, among others. For example, a deep ion etching process may be used to create a trench or matrix of channels 208 in the shape of the desired mesh pattern, which may be defined by a photoresist material applied to the surface of the medium. In any case, after formation of a suitable matrix of channels, metal to form strands 204 then may be selectively deposited into the channels to form mesh 202. For example, in an ion etching process, metal may be deposited onto the photoresist protected substrate, and a lift-off process may be used to remove excess metal, resulting in mesh 202. In some cases, a bonding layer 210, such as a thin layer of adhesive, may be selectively applied at the bottom of the etched channels, to improve the adhesion of strands 204 to the medium.

The medium and strands generally may be formed of any suitable materials. For example, the medium may be formed of material or materials that are at least substantially transparent to radiation in desired wavelength regimes, such as infrared, visible, or both, among others. Exemplary materials include silicon, germanium, and zinc selenide, among others. The strands may be formed of material or materials that are conductive and that, when formed into a suitably mesh, are capable of substantially blocking EMI. Exemplary materials include aluminum and copper, among others. The materials may be selected to facilitate manufacture of the shield, for example, an etchable medium material and a vapor depositable strand material, for shields formed by the exemplary method of ion etching and vapor deposition.

The strands, as described above, will each have an oblong cross-section oriented with a longer dimension of the cross-section aligned substantially perpendicular to an outer surface of the medium and a shorter dimension of the cross-section aligned substantially parallel to the outer surface. If the outer surface of the medium is non-planar, each strand may be oriented with the longer dimension of its cross-section aligned substantially perpendicular to a plane tangential to the outer surface of the medium and the shorter dimension of its cross-section aligned substantially parallel to the tangential plane. This orientation, in conjunction with a relatively narrow strand width, minimizes the reduction in effective aperture of the medium and thus maximizes transmission of the detection band.

When ion etching is used, the mostly vertical (i.e., anisotropic) delivery of the reactive ions may be particularly suitable for producing near vertical sidewalls, allowing the effective line width 2a of strands 204 to be kept to a minimum. According to aspects of the present teachings, low sheet resistance of mesh 202 can be achieved in conjunction with relatively narrow line widths of mesh strands 204, since the thickness (depth) t of the grid is set by the ion etch process. For example, the longer dimension of the cross-section of strands 204 may have at least twice the magnitude of the shorter dimension of the cross section (t>4a), and potentially can have up to ten or more times the magnitude of the shorter dimension (t>20a). In other words, strands 204 can be very thick (deep) compared to their width (t>>2a), whereas prior art strands 204′ are generally significantly wider than their thickness (2a′>>t′).

Mesh EMI shields potentially allow higher optical transmissions than uniform selectively transparent coatings. However, as noted previously, to realize this potential advantage, the width of mesh elements or strands must be small relative to the separation between the mesh elements, to avoid having the mesh block too much incident radiation and thereby reduce the effective aperture of the lens, window, or other medium that uses the mesh for EMI shielding. For example, for a rectangular mesh having square openings, where the mesh elements have width 2a and spacing g, the optical transmission can be calculated as the ratio of the open area between adjacent mesh elements (i.e., (g−2a)²) to the area of a unit cell defined by those mesh elements (i.e., g²):

$$T = \frac{{( g - 2 a )}^{2}}{{g}^{2}}$$

Accordingly, the advantages of EMI shielding according to the present teachings may be further understood by considering the actual transmittance of radiation in the detection band as a function of grid spacing g for various values of effective mesh line width 2a.

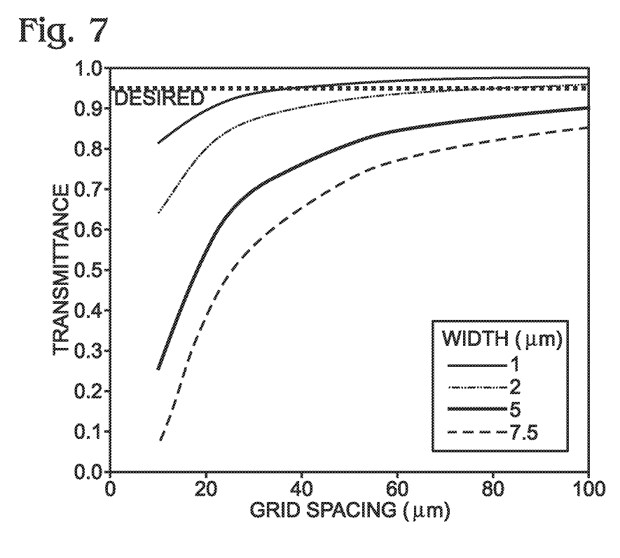

FIG. 7 shows optical transmission versus mesh spacing with mesh width 2a as a parameter for a square EMI shielding grid. It shows that to obtain >90% transmission the line width 2a should be less than 2 μm with grid spacing g greater than 40 μm. Line widths of 1 μm or less are required to achieve T>95%. However, as noted above, small line widths and large grid spacing lead to increased sheet resistance, thereby reducing the shielding effectiveness (SE) of the grid as an EMI shield.

More specifically, when the metal grid thickness is much less than the skin depth of the medium, the shielding effectiveness is almost entirely due to reflection of the incident radiation. At low frequencies, the shielding effectiveness, measured in decibels (dB) can be approximated as a constant function of the effective sheet resistance of the grid R_{eff}:

$$SE = 20 {log}_{10} ( \frac{1}{1 + \frac{\sqrt{\frac{{μ}_{0}}{{ɛ}_{0}}}}{2 {R}_{eff}}} )$$

Here, μ₀ is the permeability of free space (4π×10⁻⁷ T·m/A), ε₀ is the permittivity of free space (8.85×10⁻¹² C²/N·m²), and R_{eff} is given by the following equation:

$${R}_{eff} = \frac{g}{2 a} {R}_{c}$$

where R_{c} is the sheet resistance of the metal coating,

$${R}_{c} = \frac{1}{σ \cdot t}$$

t is the metal coating thickness, and σ is the conductivity of the metal. The expressions above show that increasing the shield effectiveness in a conventional shielding grid of given composition and thickness requires lowering the effective sheet resistance of a metallic grid by increasing the line width and/or decreasing the grid spacing.

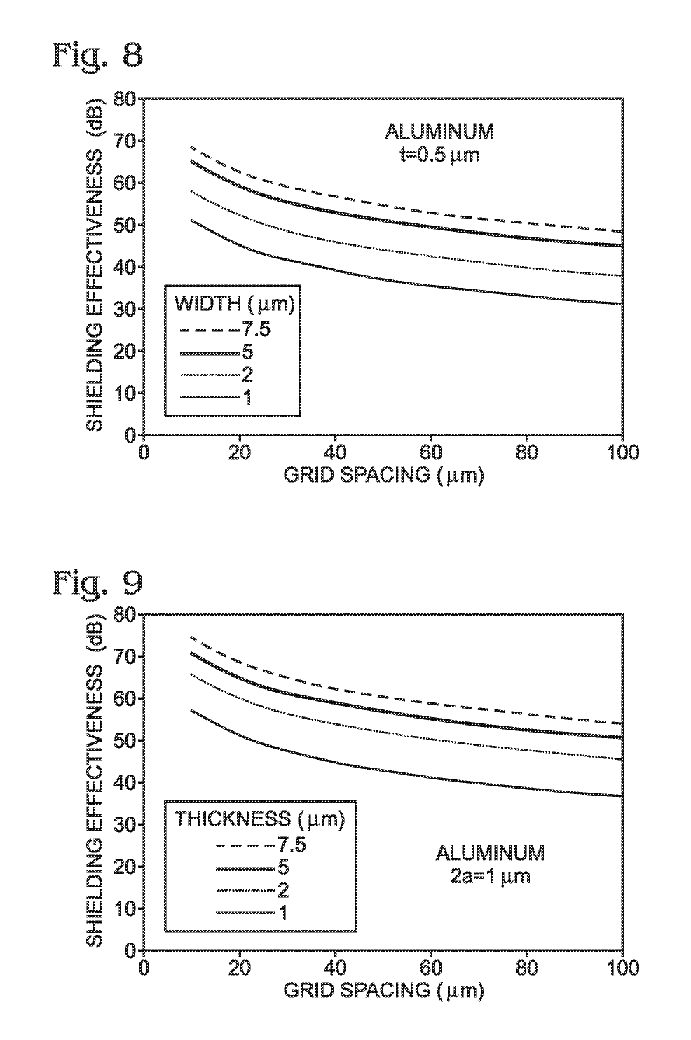

FIG. 8, for example, shows shielding effectiveness for a shielding grid fabricated using a 0.5 μm thick layer of aluminum, as a function of grid spacing and line width. FIG. 8 demonstrates that to achieve 60 dB of shielding, a grid having ≧5 μm wide lines and ≦20 μm grid spacing would be required. However, a grid with these parameters would result in an optical transmission of only around 56% and a reduction in the diffraction modulation transfer function (MTF), which is a measure of the signal-to-noise ratio for transmission through the mesh, to around only 33%. This is unacceptable for many applications, because any value of MTF not near unity indicates that transmission through the grid leads to a significant loss of information.

FIG. 9, on the other hand, shows shielding effectiveness for an EMI shielding mesh fabricated according to the present teachings, where the thickness of the grid may be viewed as a variable. More specifically, FIG. 9 shows shielding effectiveness for a grid using aluminum lines of 1 μm width, as a function of strand thickness and spacing. In FIG. 9, strand width is fixed and strand thickness (or depth) is a parameter extending up to 7.5 μm, whereas in FIG. 8, strand thickness is fixed at 0.5 μm and strand width is a parameter. This is because, according to the present teachings, strand thickness is determined by the depth of the grooves or trenches etched or otherwise formed in a medium, which may be varied to a much greater extent than the thickness of strands deposited on top of the medium as in the prior art.

The improvement in shielding performance when grid thickness may be varied is apparent in FIG. 9, which indicates that 60 dB of shielding is achieved with a grid spacing of 20 μm and a thickness of 2.8 μm, even though the strand width is only 1 μm. In this case, the strands only cover about one tenth of the two-dimensional medium aperture, resulting in an optical transmission of about 90% and a reduction of MTF of only about 5%. This may be compared to the grid performance depicted in FIG. 8, where the same 60 dB of shielding was achieved with a strand width of 5 μm, so that the grid strands cover almost half of the medium aperture. As described above, this results in an optical transmission of approximately 56% and a potentially unacceptable reduction of MTF of around two-thirds.

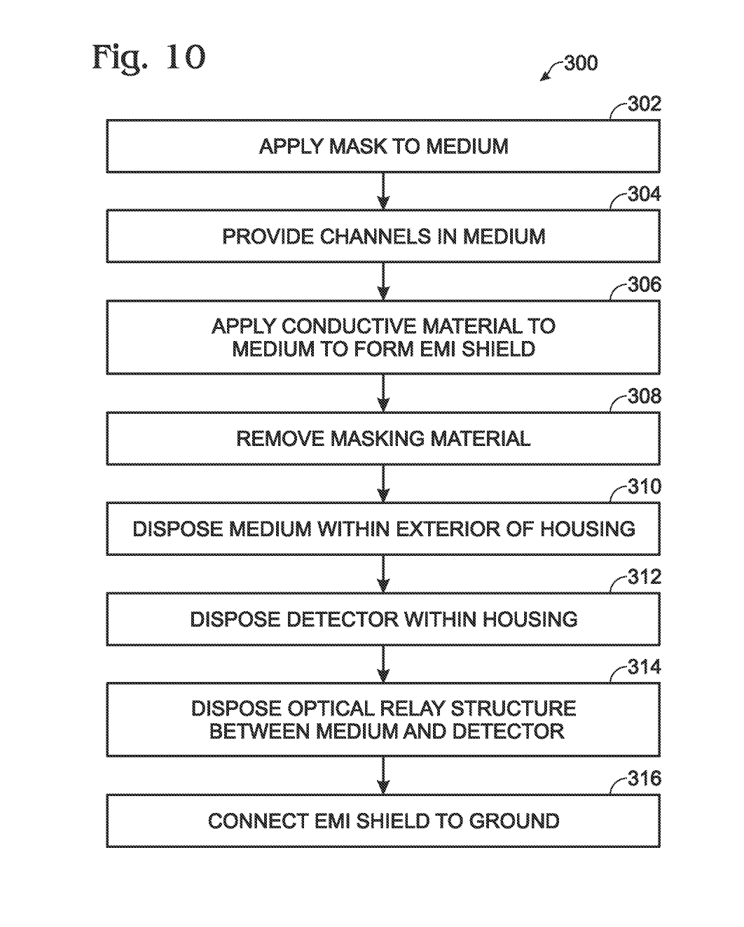

FIG. 10 is a flowchart depicting an exemplary method of manufacturing an EMI shielded detection system, generally indicated at 300, according to aspects of the present teachings. The system, more generally, may be manufactured using any suitable technique. The steps described below, or subsets thereof, may for performed in any suitable order, including the order in which they are described, any suitable number of times.

At step 302, a photoresist material or other form of mask is applied to the top surface of a transparent medium such as a window or lens in a manner configured to allow subsequent formation of a desired pattern of grooves in the medium. For example, if a positive resist material is used with a photoresist process, it may be exposed to developing light in the regions of a desired mesh pattern, so that those regions become soluble to subsequent application of a photoresist developer.

At step 304, the transparent medium is provided with a pattern of channels or grooves, which may be thought of as an integrally formed or monolithic support matrix for subsequent deposition of a conductor, extending from the top surface of the medium into the body of the medium. As described previously, this may be accomplished by ion etching or laser scribing, among others. When ion etching is performed, the ions may include the photoresist developer so that the photoresist is developed and the medium is etched in a single step. Alternatively, the photoresist developer may be applied to form a well-defined mask on the surface of the medium, after which the medium may be etched or scribed by another suitable technique.

At step 306, a conductive material, typically a metal such as aluminum, is applied to the surface of the medium and any remaining photoresist material, in a sufficient quantity to fill in the channels or grooves that have been formed in the medium. This results in the formation of a mesh of conductive strands embedded in the medium. These strands may have any desired dimensions and spacing to produce a desired EMI shielding effect, as described previously. In particular, the strands formed at step 306 may have depths that exceed their widths, and that in some cases may be at least twice as deep within the medium as they are wide.

At step 308, any remaining masking material such as photoresist material is peeled off or otherwise removed, removing any excess conductive material that may have formed on top of the photoresist during application of the conductive material and formation of the conductive strands at step 306. This leaves just the conductive mesh embedded in the medium, which will act as an EMI shield as it will have been configured to allow substantial passage of radiation in the detection band, such as visible light and/or infrared radiation, while preventing substantial passage of EMI radiation, such as microwave radiation and/or radio waves. As described above, due to the relatively large thickness (or depth) and relatively small width of strands deposited according to the present teachings, sufficient EMI shielding may be accomplished with relatively high levels of detection band transmittance and acceptable amounts of diffraction in the detection band.

At step 310, the medium may be disposed within the exterior of a detector housing configured to allow incoming radiation to reach the medium and selectively enter the housing.

At step 312, a detector may be disposed within the housing.

At step 314, an optical relay structure may be disposed between the medium and the detector, and configured to focus and/or direct detection band radiation transmitted through the medium onto the detector.

At step 316, the EMI shield formed of conductive mesh embedded in the medium may be connected to an electrical ground, for example, by connection to a metallic surface of the housing.

In some embodiments, additional steps may include associated the detector and/or housing with a gimbal system, connecting the detector, gimbal system, etc., to suitable controllers, and so on.

### EXAMPLES

This section describes exemplary electromagnetic interference shields, in accordance with aspects of the present disclosure, presented without limitation as a series of numbered paragraphs.

1. A shielded detection system, comprising (A) an infrared radiation detector configured to detect infrared radiation; (B) a housing at least substantially surrounding the detector and including a window substantially transparent to infrared radiation; and (C) an optical relay structure operatively disposed between the window and the detector and configured to direct infrared radiation transmitted through the window onto the infrared radiation detector; wherein the window includes an electrically conductive mesh configured to allow substantial passage of infrared radiation into the housing while preventing substantial passage of microwave radiation; wherein the mesh is formed of strands each having an oblong cross-section oriented with a longer dimension of the cross-section aligned substantially perpendicular to an outer surface of the window and a shorter dimension of the cross-section aligned substantially parallel to the outer surface; and wherein the conductive mesh is connected to an electrical ground.

2. The shielded detection system of paragraph 1, further comprising a visible light detector configured to detect visible light, wherein the window is further configured to allow passage of visible light, and wherein the optical relay structure is further configured to direct visible light transmitted through the window onto the visible light detector.

3. The shielded detection system of paragraph 1 or 2, wherein the window includes an integrally formed support matrix substantially transmissive to infrared radiation, and wherein the electrically conductive mesh is disposed within the matrix.

4. The shielded detection system of paragraph 3, wherein the support matrix is selected from the group consisting of silicon, germanium, and zinc selenide.

5. The shielded detection system of paragraph 3, wherein the support matrix includes a plurality of channels, and wherein the conductive mesh is disposed within the channels.

6. The shielded detection system of paragraph 5, wherein the channels are grooves formed in a surface of the support matrix.

7. The shielded detection system of any preceding paragraph, wherein the conductive mesh includes a metal.

8. The shielded detection system of any preceding paragraph, wherein the conductive mesh defines spaces between the strands through which infrared radiation can pass, and wherein the spaces are larger than the wavelengths of infrared radiation detected by the detector and smaller than the wavelengths of microwave radiation blocked by the window.

9. The shielded detection system of any preceding paragraph, wherein the housing is electrically conductive, and wherein the conductive mesh is grounded to the housing.

10. The shielded detection system of any preceding paragraph, wherein the longer dimension of the cross-section has at least twice the magnitude of the shorter dimension of the cross section.

11. The shielded detection system of any preceding paragraph, further comprising a gimbal assembly formed at least in part by the housing and configured to controllably pivot the detector about at least two nonparallel axes.

12. The shielded detection system of paragraph 11, further comprising a gimbal mount supporting the gimbal assembly, wherein the gimbal assembly is configured to pivot the detector with respect to the gimbal mount.

13. The shielded detection system of any preceding paragraph, wherein the window is configured to provide at least approximately 90% transmission of infrared radiation.

14. The shielded detection system of paragraph 13, wherein the window is configured to provide a diffraction modulation transfer function of at least approximately 90% for infrared radiation.

15. The shielded detection system of any preceding paragraph, wherein the window comprises a lens.

16. A shielded detection system, comprising (A) an infrared radiation detector configured to detect infrared radiation; (B) a housing at least substantially surrounding the detector and including a window, the window including a monolithic support matrix transmissive to infrared radiation and an electrically conductive mesh opaque to microwave radiation, the conductive mesh being disposed within the support matrix and connected to an electrical ground; and (D) an optical relay structure operatively disposed between the window and the detector and configured to direct infrared radiation transmitted through the window onto the detector.

17. The shielded detection system of paragraph 16, wherein the support matrix includes a plurality of channels, and wherein the conductive mesh is disposed within the channels.

18. A shielded detection system, comprising (A) a detector configured to detect electromagnetic radiation; (B) a housing at least substantially surrounding the detector and including a window configured to allow substantial passage of radiation having wavelengths less than a predetermined wavelength threshold into the housing while preventing substantial passage of radiation having wavelengths greater than the threshold; and (C) an optical relay structure operatively disposed between the window and the detector and configured to direct radiation transmitted through the window onto the detector; wherein the window includes an electrically conductive mesh formed of strands each having an oblong cross-section defining a longer dimension and a shorter dimension; and wherein each strand is oriented with the longer dimension of its cross-section aligned substantially perpendicular to a plane tangential to an outer surface of the window and the shorter dimension of its cross-section aligned substantially parallel to the tangential plane.

19. The system of paragraph 18, wherein the window is configured to allow substantial passage of visible light and to prevent substantial passage of radio waves.

20. The system of paragraph 18 or 19, wherein the window is configured to allow substantial passage of infrared radiation and to prevent substantial passage of microwave radiation.

21. The system of any of paragraphs 18 to 20, wherein the window is configured to provide at least approximately 90% transmission for radiation having wavelengths less than the predetermined wavelength threshold and also to provide a diffraction modulation transfer function of at least approximately 90% for radiation having wavelengths less than the predetermined wavelength threshold.

22. The system of any of paragraphs 18 to 21, wherein the window comprises a lens.

23. A method of manufacturing an EMI shielded detection system, comprising (A) applying a mask to a medium at least partially transparent to incident electromagnetic radiation; (B) providing a pattern of channels in the medium; (C) applying a conductive material to an outer surface of the medium in a sufficient quantity to fill in the channels and form a mesh of conductive strands embedded in the medium; and (D) removing any excess conductive material from the outer surface of the medium; (E) disposing the medium within a detector housing configured to allow incoming radiation to reach the medium and selectively enter the housing; and (F) disposing within the housing a detector configured to detect at least a portion of the radiation entering the housing; wherein the strands have an oblong cross-section oriented with a longer dimension of the cross-section aligned substantially perpendicular to the outer surface of the medium and a shorter dimension of the cross-section aligned substantially parallel to the outer surface.

24. The method of paragraph 23, wherein the mask is a photoresist mask and providing the pattern of channels includes ion etching the medium.

25. The method of paragraph 23 or 24, wherein the strands are at least twice as deep within the medium as they are wide.

26. The method of any of paragraphs 23 to 25, wherein the mesh is configured to allow substantial passage of infrared radiation and to prevent substantial passage of microwave radiation, and wherein the detector is an infrared detector.

27. A shielded detection system according to any of paragraphs 1 to 22, and/or a method of manufacturing an EMI shielded detection system according to any of paragraphs 23 to 26, substantially as hereinbefore described and with reference to the accompanying drawings.

The disclosure set forth above may encompass multiple distinct inventions with independent utility. Although each of these inventions has been disclosed in its preferred form(s), the specific embodiments thereof as disclosed and illustrated herein are not to be considered in a limiting sense, because numerous variations are possible. The subject matter of the inventions includes all novel and nonobvious combinations and subcombinations of the various elements, features, functions, and/or properties disclosed herein. For example, although the inventions are described in terms of a shielded imaging system, the claims might focus on components of an imaging system, such as a lens, filter, and/ or other optic configured as described herein to provide EMI shielding. The following claims particularly point out certain combinations and subcombinations regarded as novel and nonobvious. Inventions embodied in other combinations and subcombinations of features, functions, elements, and/or properties may be claimed in applications claiming priority from this or a related application. Such claims, whether directed to a different invention or to the same invention, and whether broader, narrower, equal, or different in scope to the original claims, also are regarded as included within the subject matter of the inventions of the present disclosure.

1. A shielded detection system, comprising:
an infrared radiation detector configured to detect infrared radiation;
a housing at least substantially surrounding the detector and including a window substantially transparent to infrared radiation; and
an optical relay structure operatively disposed between the window and the detector and configured to direct infrared radiation transmitted through the window onto the infrared radiation detector;
wherein the window includes an electrically conductive mesh configured to allow substantial passage of infrared radiation into the housing without substantially polarizing the infrared radiation and while preventing substantial passage of microwave radiation;
wherein the mesh is formed of strands each having an oblong cross-section oriented with a longer dimension of the cross-section aligned substantially perpendicular to an outer surface of the window and a shorter dimension of the cross-section aligned substantially parallel to the outer surface; and
wherein the conductive mesh is connected to an electrical ground.

2. The shielded detection system of claim 1, further comprising a visible light detector configured to detect visible light, wherein the window is further configured to allow passage of visible light, and wherein the optical relay structure is further configured to direct visible light transmitted through the window onto the visible light detector.

3. The shielded detection system of claim 1, wherein the window includes an integrally formed support matrix substantially transmissive to infrared radiation, and wherein the electrically conductive mesh is disposed within the matrix.

4. The shielded detection system of claim 3, wherein the support matrix is selected from the group consisting of silicon, germanium, and zinc selenide.

5. The shielded detection system of claim 3, wherein the support matrix includes a plurality of channels, and wherein the conductive mesh is disposed within the channels.

6. The shielded detection system of claim 5, wherein the channels are grooves formed in a surface of the support matrix.

7. The shielded detection system of claim 1, wherein the conductive mesh includes a metal.

8. The shielded detection system of claim 1, wherein the conductive mesh defines spaces between the strands through which infrared radiation can pass, and wherein the spaces are larger than the wavelengths of infrared radiation detected by the detector and smaller than the wavelengths of microwave radiation blocked by the window.

9. The shielded detection system of claim 1, wherein the housing is electrically conductive, and wherein the conductive mesh is grounded to the housing.

10. The shielded detection system of claim 1, wherein the longer dimension of the cross-section has at least twice the magnitude of the shorter dimension of the cross section.

11. The shielded detection system of claim 1, further comprising a gimbal assembly formed at least in part by the housing and configured to controllably pivot the detector about at least two nonparallel axes.

12. The shielded detection system of claim 11, further comprising a gimbal mount supporting the gimbal assembly, wherein the gimbal assembly is configured to pivot the detector with respect to the gimbal mount.

13. The shielded detection system of claim 1, wherein the window is configured to provide at least approximately 90% transmission of infrared radiation.

14. The shielded detection system of claim 13, wherein the window is configured to provide a diffraction modulation transfer function of at least approximately 90% for infrared radiation.

15. The shielded detection system of claim 1, wherein the window comprises a lens.

16. A shielded detection system, comprising:
an infrared radiation detector configured to detect infrared radiation;
a housing at least substantially surrounding the detector and including a window, the window including a monolithic support matrix transmissive to infrared radiation and an electrically conductive mesh opaque to microwave radiation and transmissive to infrared radiation without substantially polarizing the infrared radiation, the conductive mesh being disposed within the support matrix and connected to an electrical ground; and
an optical relay structure operatively disposed between the window and the detector and configured to direct infrared radiation transmitted through the window onto the detector,
wherein the mesh is formed of strands each having an oblong cross-section oriented with a longer dimension of the cross-section aligned substantially perpendicular to an outer surface of the window and a shorter dimension of the cross-section aligned substantially parallel to the outer surface.

17. The shielded detection system of claim 16, wherein the support matrix includes a plurality of channels, and wherein the conductive mesh is disposed within the channels.

18. A shielded detection system, comprising:
a detector configured to detect electromagnetic radiation;
a housing at least substantially surrounding the detector and including a window configured to allow substantial passage of radiation having wavelengths less than a predetermined wavelength threshold into the housing without substantially polarizing the radiation and while preventing substantial passage of radiation having wavelengths greater than the threshold; and
an optical relay structure operatively disposed between the window and the detector and configured to direct radiation transmitted through the window onto the detector;
wherein the window includes an electrically conductive mesh formed of strands each having an oblong cross-section defining a longer dimension and a shorter dimension; and
wherein each strand is oriented with the longer dimension of its cross-section aligned substantially perpendicular to a plane tangential to an outer surface of the window and the shorter dimension of its cross-section aligned substantially parallel to the tangential plane.

19. The system of claim 18, wherein the window is configured to allow substantial passage of visible light and to prevent substantial passage of radio waves.

20. The system of claim 18, wherein the window is configured to allow substantial passage of infrared radiation and to prevent substantial passage of microwave radiation.

21. The system of claim 18, wherein the window is configured to provide at least approximately 90% transmission for radiation having wavelengths less than the predetermined wavelength threshold and also to provide a diffraction modulation transfer function of at least approximately 90% for radiation having wavelengths less than the predetermined wavelength threshold.

22. The system of claim 18, wherein the window comprises a lens.

23. A method of manufacturing an EMI shielded detection system, comprising:
applying a mask to a medium at least partially transparent to incident electromagnetic radiation;
providing a pattern of channels in the medium;
applying a conductive material to an outer surface of the medium in a sufficient quantity to fill in the channels and form a mesh of conductive strands embedded in the medium;
removing any excess conductive material from the outer surface of the medium;
disposing the medium within a detector housing configured to allow incoming radiation to reach the medium and selectively enter the housing; and
disposing within the housing a detector configured to detect at least a portion of the radiation entering the housing;
wherein the strands have an oblong cross-section oriented with a longer dimension of the cross-section aligned substantially perpendicular to the outer surface of the medium and a shorter dimension of the cross-section aligned substantially parallel to the outer surface, wherein the detector is an infrared detector, and wherein the mesh is configured to allow substantial passage of infrared radiation without substantially polarizing the infrared radiation and while preventing substantial passage of microwave radiation.

24. The method of claim 23, wherein the mask is a photoresist mask and providing the pattern of channels includes ion etching the medium.

25. The method of claim 23, wherein the strands are at least twice as deep within the medium as they are wide.

26. (canceled)
